(19) United States
(12) Patent Application Publication
(10) Pub. No.: US 2024/0065103 A1
(43) Pub. Date: Feb. 22, 2024

(54) THERMOELECTRIC CONVERSION ELEMENT, THERMOELECTRIC CONVERSION ELEMENT ARRAY, INFRARED SENSOR, AND METHOD FOR MANUFACTURING THERMOELECTRIC CONVERSION ELEMENT

(71) Applicant: Sony Group Corporation, Tokyo (JP)

(72) Inventors: Ryota OISHI, Tokyo (JP); Koji KADONO, Tokyo (JP); Shinji IMAIZUMI, Tokyo (JP)

(21) Appl. No.: 18/271,617

(22) PCT Filed: Dec. 15, 2021
(86) PCT No.: PCT/JP2021/046172

§ 371 Date: Jul. 10, 2023

(30) Foreign Application Priority Data
Jan. 15, 2021 (JP) 2021-004874

(51) Int. Cl. H10N 10/17; H10N 10/01; H10N 10/855

(52) U.S. Cl. CPC H10N 10/17; H10N 10/01; H10N 10/855

(57) ABSTRACT

A thermoelectric conversion element 10 includes: a substrate 11; a first electrode 12 on a high temperature side which is disposed on a front surface of the substrate 11; a second electrode 13 on a low temperature side which is disposed on a front surface of the substrate 11; a thermal conductor 14 which connects the first electrode 12 and the second electrode 13 to each other and contains a nanostructure; and an absorption film 15 which is formed on a front surface of the first electrode 12 and absorbs incident light. The thermal conductor 14 is provided at a position separated from the substrate 11. In the thermoelectric conversion element 10, the absorption film 15 may be an infrared absorption film, and the incident light may have a wavelength in a range of 4 μm to 12 μm.

### TECHNICAL FIELD

The present technology relates to a technology using a thermoelectric conversion element, and more particularly to a thermoelectric conversion element having a nanostructure, a thermoelectric conversion element array, an infrared sensor, and a method for manufacturing a thermoelectric conversion element.

### BACKGROUND ART

In recent years, graphene, which is a nanostructure, has attracted attention as an electronic material in the field of nanotechnology for applications to electronic devices such as sensors. Graphene has features such as thinness, high electrical conductivity, high thermal conductivity, and high mechanical strength.

On the other hand, there is a thermoelectric conversion type infrared sensor called a thermopile as one type of infrared sensor. A thermoelectric conversion type infrared sensor is inferior to a quantum type infrared sensor in terms of high speed response and high sensitivity, but has features such as being able to operate at room temperature and not requiring a power source.

Here, a thermoelectric conversion type infrared sensor using graphene, which is a nanocarbon material, is known. For example, PTL 1 proposes a thermal device that includes three-dimensional porous graphene and a pair of electrodes disposed facing each other on the three-dimensional porous graphene.

Furthermore, there is known a technology of forming a graphene nanoribbon, which is a structure with a narrow line width, using graphene. For example, PTL 2 proposes a graphene structure that includes a substrate, a first electrode formed on the substrate, a graphene nanoribbon formed on the substrate, and a second electrode formed on the substrate, and in which the first electrode and one end of the graphene nanoribbon are connected to each other, the other end of the graphene nanoribbon and the second electrode are connected to each other, and the width of the graphene nanoribbon is 100 nm or less, which causes a width of a forbidden body as a semiconductor.

### CITATION LIST

### Patent Literature

### [PTL 1]

JP 2018-37617A

### [PTL 2]

JP 2013-253010A

### SUMMARY

### Technical Problem

In the technology of PTL 1, a thermal conductor with a large volume, which is stacked as a composite material to form a thick film of about 5 to 10 μm, is used. This is because the thermal conductor using the nanocarbon material also serves as an infrared absorption film, and therefore it is necessary to increase the absorption rate by making the film thicker. As a result, in the technology of PTL 1, thermal capacity increases, and thus high sensitivity can be realized, but a thermoelectromotive force type infrared sensor that achieves both high sensitivity and high speed response cannot be obtained.

Further, the technology of PTL 2 proposes a quantum type infrared sensor in which graphene is used as an absorption film that absorbs a wide range of light wavelengths by utilizing features that a bandgap of the graphene changes continuously. However, the quantum type infrared sensor requires cooling, which increases the size of the sensor device as a whole. Further, the technology of PTL 2 does not propose a thermoelectric conversion type infrared sensor that utilizes an extremely small volume of graphene and achieves both high sensitivity and high speed response.

Therefore, a main object of the present technology is to provide a thermoelectric conversion element that achieves both high sensitivity and high speed response.

### Solution to Problem

A thermoelectric conversion element according to the present technology includes: a substrate; a first electrode on a high temperature side which is disposed on a front surface of the substrate; a second electrode on a low temperature side which is disposed on a front surface of the substrate; a thermal conductor which connects the first electrode and the second electrode to each other and contains a nanostructure; and an absorption film which is formed on a front surface of the first electrode and absorbs incident light. In the thermoelectric conversion element according to the present technology, the absorption film may be an infrared absorption film, and the incident light preferably has a wavelength in a range of 4 μm to 12 μm.

In the thermoelectric conversion element according to the present technology, the absorption film formed on the front surface of the first electrode absorbs black body light from a body temperature of a person or a heat source, and the absorption film is heated with the light (a photothermal conversion process). Subsequently, the first electrode under the absorption film is heated, and a temperature difference occurs between the first electrode and the second electrode. Finally, a temperature difference occurs between both end portions of the thermal conductor sandwiched between the first electrode and the second electrode, generating a thermoelectromotive force (a thermoelectric conversion process). Therefore, the thermoelectric conversion element according to the present technology functions as an infrared sensor by converting infrared light into an electric signal through two physical processes of the photothermal conversion process and the thermoelectric conversion process.

In the thermoelectric conversion element according to the present technology, a material of the thermal conductor may be a carbon material with which an absorption rate difference between the absorption film and the thermal conductor is 60% or more. The thermal conductor may have a thermal resistance of 2.5×10⁷ (K/W) or more. The thermal conductor may be provided at a position separated from the substrate. A material of the first electrode may be nickel or titanium. A material of the second electrode may be gold or aluminum. A width of the thermal conductor may increase from the first electrode toward the second electrode. The absorption film may be provided with a heat collection structure. The first electrode and the second electrode may have different thicknesses, and the thermal conductor may be bent to provide curvature. The substrate may be formed of a thermal resonance reflection film.

In addition, a thermoelectric conversion element array according to the present technology includes: a plurality of the thermoelectric conversion elements according to the present technology, wherein a material of the thermal conductor is a carbon material, and the thermoelectric conversion elements are connected to each other by a metal having a polarity of thermoelectric performance different from that of the carbon material. Furthermore, the thermoelectric conversion element according to the present technology can be used for a plurality of infrared line sensors disposed in a line array and can also be used for a plurality of infrared image sensors disposed in a two-dimensional array.

In addition, a method for manufacturing a thermoelectric conversion element according to the present technology includes: patterning a second electrode on a low temperature side and a thermal conductor having one end connected to the second electrode on a front surface of a substrate; patterning a first electrode on a high temperature side connected to the other end of the thermal conductor on the front surface of the substrate; forming an absorption film that absorbs incident light on the front surface of the first electrode; and forming the thermal conductor with a nanostructure at a position separated from the substrate.

### Advantageous Effects of Invention

According to the present technology, it is possible to provide a thermoelectric conversion element that achieves both high sensitivity and high speed response. The effect is not necessarily limited. Any effect described in the present specification or other effects achievable from the present specification may be obtained in addition to the foregoing effect or instead of the foregoing effect.

### BRIEF DESCRIPTION OF DRAWINGS

FIG. 1 is a schematic view showing a configuration example of a thermoelectric conversion element according to a first embodiment of the present technology.

FIG. 2 is a schematic view showing a modification example of the thermoelectric conversion element according to the first embodiment of the present technology.

FIG. 3 is a graph showing a range of an infrared absorption wavelength of the thermoelectric conversion element according to the first embodiment of the present technology.

FIG. 4 is a graph showing the amount of infrared light detected by the thermoelectric conversion element according to the first embodiment of the present technology.

FIG. 5 is a table showing optical conditions of incident light used for the thermoelectric conversion element according to the first embodiment of the present technology.

FIG. 6 is a table showing material conditions used for a thermal conductor of the thermoelectric conversion element according to the first embodiment of the present technology.

FIG. 7 is a table showing examples and comparative examples of the thermoelectric conversion element according to the first embodiment of the present technology.

FIG. 8 is a table showing examples and comparative examples of an infrared sensor using the thermoelectric conversion element according to the first embodiment of the present technology.

FIG. 9 is a plan view showing examples of a heat collection structure of an absorption film provided in the thermoelectric conversion element according to the first embodiment of the present technology.

FIG. 10 is a schematic view showing a configuration example of a thermoelectric conversion element according to a second embodiment of the present technology.

FIG. 11 is a graph showing a resonance absorption spectrum of the thermoelectric conversion element according to the second embodiment of the present technology.

FIG. 12 is a schematic view showing a configuration example of a thermoelectric conversion element according to a third embodiment of the present technology.

FIG. 13 is a schematic view showing a configuration example of a thermoelectric conversion element according to a fourth embodiment of the present technology.

FIG. 14 is a schematic view showing an example of a method for manufacturing a photothermoelectric conversion element according to the present technology.

FIG. 15 is a schematic view showing an example of a method for manufacturing a photothermoelectric conversion element according to the present technology.

FIG. 16 is a schematic view showing an example of a method for manufacturing a photothermoelectric conversion element according to the present technology.

FIG. 17 is a schematic view showing an example of a method for manufacturing a photothermoelectric conversion element according to the present technology.

FIG. 18 is a schematic view showing an example of a method for manufacturing a photothermoelectric conversion element according to the present technology.

FIG. 19 is a schematic view showing an example of a method for manufacturing a photothermoelectric conversion element according to the present technology.

FIG. 20 is a schematic view showing an example of a method for manufacturing a photothermoelectric conversion element according to the present technology.

FIG. 21 is a schematic view showing an example of a method for manufacturing a photothermoelectric conversion element according to the present technology.

FIG. 22 is a schematic view showing an example of a method for manufacturing a photothermoelectric conversion element according to the present technology.

FIG. 23 is a schematic view showing an example of a method for manufacturing a photothermoelectric conversion element according to the present technology.

FIG. 24 is a schematic view showing an example of a method for manufacturing a photothermoelectric conversion element according to the present technology.

FIG. 25 is a schematic view showing an example of a method for manufacturing a photothermoelectric conversion element according to the present technology.

FIG. 26 is a schematic view showing an example of a method for manufacturing an infrared sensor using a thermoelectric conversion element according to the present technology.

FIG. 27 is a schematic view showing an example of a method for manufacturing an infrared sensor using a thermoelectric conversion element according to the present technology.

FIG. 28 is a schematic view showing an example of a method for manufacturing an infrared sensor using a thermoelectric conversion element according to the present technology.

FIG. 29 is a schematic view showing an example of a method for manufacturing an infrared sensor using a thermoelectric conversion element according to the present technology.

FIG. 30 is a schematic view showing an example of a method for manufacturing an infrared sensor using a thermoelectric conversion element according to the present technology.

FIG. 31 is a schematic view showing an example of a method for manufacturing an infrared sensor using a thermoelectric conversion element according to the present technology.

FIG. 32 is a schematic view showing an example of a method for manufacturing an infrared sensor using a thermoelectric conversion element according to the present technology.

FIG. 33 is a schematic view showing an example of a method for manufacturing an infrared sensor using a thermoelectric conversion element according to the present technology.

FIG. 34 is a schematic view showing an example of a method for manufacturing an infrared sensor using a thermoelectric conversion element according to the present technology.

FIG. 35 is a schematic view showing an example of a method for manufacturing an infrared sensor using a thermoelectric conversion element according to the present technology.

FIG. 36 is a schematic view showing an example of a method for manufacturing an infrared sensor using a thermoelectric conversion element according to the present technology.

FIG. 37 is a schematic view showing an example of a method for manufacturing an infrared sensor using a thermoelectric conversion element according to the present technology.

### DESCRIPTION OF EMBODIMENTS

Hereinafter, preferable embodiments for implementing the present technology will be described with reference to the drawings. The embodiments which will be described later illustrate examples of typical embodiments of the present technology, and any of the embodiments can be combined with each other. Moreover, the scope of the present technology should not be interpreted narrower by the embodiments. The description will proceed in the following order:
1. First Embodiment
(1) Overview of Thermoelectric Conversion Type Infrared Sensor
(2) Configuration Example of Thermoelectric Conversion Element 10
(3) Configuration of Thermoelectric Conversion Element 20 of Modification Example
(4) Examples of Thermoelectric Conversion Element 10
(5) Configuration Example of Heat Collection Structure
2. Second Embodiment
3. Third Embodiment
4. Fourth Embodiment
5. Example of Method for Manufacturing Photothermoelectric Conversion Element
6. Example of Method for Manufacturing Infrared Sensor

### 1. First Embodiment

### (1) Overview of Thermoelectric Conversion Type Infrared Sensor

First, an overview of a thermoelectric conversion type infrared sensor will be described.

In the field of electronic devices, research and development of an infrared sensor and an infrared image sensor are being vigorously pursued on the basis of mature design and process technology for a visible light image sensor.

An infrared sensor capable of high speed response and high sensitivity sensing is predominantly of a so-called “quantum type”, which is the same as a visible light image sensor. However, in the case of the “quantum type” infrared sensor, since noise in a room temperature environment is large, it is necessary to cool the sensor with a Peltier element or liquid nitrogen. Therefore, there is a problem that the entire sensor device becomes large.

The detection performance of the thermoelectric conversion type infrared sensor becomes more sensitive as a thermoelectromotive force generated due to a temperature difference between a pair of electrodes provided in a thermal conductor increases. The magnitude of the thermoelectromotive force is determined by the amount of infrared light from an absorption film of the infrared sensor, the thermal resistance of the thermal conductor, and a Seebeck coefficient, which is a physical property of a material of the thermal conductor. Further, in designing a sensor structure, a design in which the output voltage is increased by serially connecting a plurality of thermoelectric elements to one pixel is also used.

Silicon, which has a relatively large Seebeck coefficient and is well developed in microfabrication technology, is used as a material for the thermoelectric conversion type infrared sensor of the related art. Further, the frame rate of the thermoelectric conversion type infrared sensor is determined by the response speed (the time constant), which is determined by the thermal resistance and the thermal capacity of the thermal conductor. For this reason, a thermoelectric conversion type infrared sensor with a high frame rate is required to have a thermal conductor with a small thermal resistance and a small thermal capacity.

As described above, the higher the thermal resistance, the higher the sensitivity of the thermoelectric conversion type infrared sensor. Therefore, the value of the thermal resistance is adjusted and designed to satisfy high sensitivity and high speed response. For high speed response, a design is mainly made to reduce the thermal capacity of the thermal conductor.

The thermal capacity is determined by a specific heat and a density, which are physical properties of the material of the thermal conductor, and the volume of the thermal conductor. As means of reducing the thermal capacity, instead of silicon, the use of a carbon material, which has a low specific heat and a low density, is being studied.

In addition to these physical properties of the material, the arrangement of thermal conductors in a thermoelectric conversion type infrared sensor element is designed to create a structure in which the thermal conductor is isolated from a solid or a gas, which serves as a heat escape route, such as the substrate or the atmosphere. Further, a design of the infrared sensor in which the output voltage is increased by serially connecting a plurality of thermoelectric conversion elements to one pixel is also used.

However, in the designing of the structure, the cost increases due to the complexity of a manufacturing process, or in the case of serial connection, there is a problem that the number of thermal conductors which can be connected to the one pixel is limited due to manufacturing variations. Therefore, the development of a thermoelectric conversion type infrared sensor with high sensitivity and high speed response is being diligently pursued, but it cannot be said that the performance is sufficient yet.

Therefore, in the present technology, by providing a thermal conductor that contains a nanostructure, it is possible to provide a thermoelectric conversion element that achieves both high sensitivity and high speed response and an infrared sensor using the thermoelectric conversion element.

### (2) Configuration Example of Thermoelectric Conversion Element 10

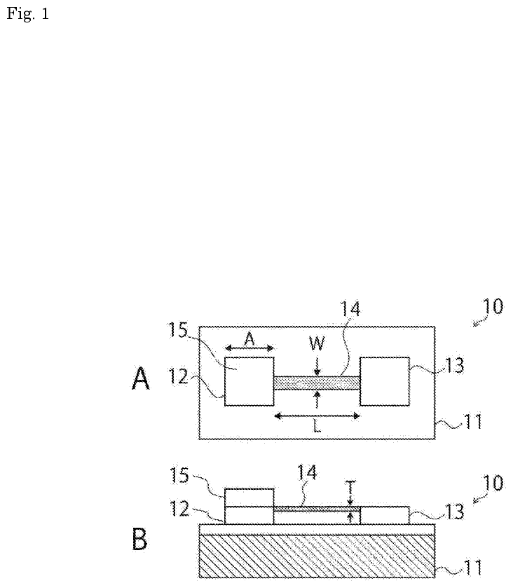

Next, a configuration example of a thermoelectric conversion element 10 according to a first embodiment of the present technology will be described with reference to FIG. 1. FIG. 1 is a schematic view showing the configuration example of the thermoelectric conversion element 10.

As shown in FIG. 1, the thermoelectric conversion element 10 includes, as an example, a substrate 11, a hot point electrode 12 as a first electrode on a high temperature side which is disposed on a front surface of the substrate 11, a cold point electrode 13 as a second electrode on a low temperature side which is disposed on a front surface of the substrate 11, a thermal conductor 14 which connects the hot point electrode 12 and the cold point electrode 13 to each other and contains a nanostructure, and an absorption film 15 which is formed on a front surface of the hot point electrode 12 and absorbs incident light.

The hot point electrode 12 has a role as a hot point electrode, and for example, nickel or titanium can be used as a material thereof. Also, the cold point electrode 13 has a role as a cold point electrode, and for example, gold or aluminum can be used as a material thereof.

The thermal conductor 14 is provided at a position separated from the substrate 11 and connects the hot point electrode 12 and the cold point electrode 13 to each other in a shape of a beam that serves as a hollow structure. As an example, the thermal conductor 14 can use a graphene nanoribbon as a material thereof. Moreover, the thermal conductor 14 is preferably made of a carbon material with which an absorption rate difference between the absorption film and the thermal conductor is 60% or more. Furthermore, the thermal conductor 14 preferably has a thermal resistance of 2.5×10⁷ (K/W) or more.

More specifically, a width W of the graphene nanoribbon is preferably 100 nm or more and 1 μm or less and more preferably 100 nm or more and 500 nm or less, in which properties as a semimetal can be expected. Further, a thickness T of the graphene nanoribbon is preferably in the range of 0.3 nm to 15 nm and more preferably 0.3 nm to 10 nm, in which an absorption rate of the infrared ray is low. In addition, a length L of the graphene nanoribbon is preferably 500 nm or more and 50 μm or less and more preferably 500 nm or more and 5 μm or less, which is a range allowing easy formation of a hollow structure and a large distance between both electrodes. Specific combinations of these shapes are shown in the examples below.

When the size of the graphene nanoribbon is adjusted within the above range, an absorption rate difference between the absorption film 15 and the thermal conductor 14 is 60% or more, and the thermal conductor 14 has a thermal resistance of 2.5×10⁷ (K/W) or more.

As an example, the absorption film 15 is preferably an infrared absorption film. Moreover, the wavelength of the incident light with which the absorption film 15 is irradiated is preferably in the range of 4 μm to 12 μm. The wavelength of the incident light is more preferably in the range of 8 μm to 10 μm. The absorption film 15 transfers the heat absorbed from the incident light to the thermal conductor 14 via the hot point electrode 12.

Here, in the thermoelectric conversion element of the related art using a nanocarbon material, the nanocarbon material is used as both an infrared absorber and a thermal conductor. In such a thermoelectric conversion element of the related art, a thick film (composite) nanocarbon material is used in order to increase an infrared absorption rate, but the thick film has a large volume, which in turn increases the thermal capacity, resulting in a slow response speed.

On the other hand, in the thermoelectric conversion element 10 according to the present embodiment, the functions of the infrared absorber and the thermal conductor are separated from each other, and a nanocarbon material is used for the thermal conductor (wiring) 14. The absorption film 15 is separately provided on the hot point electrode 12 as an infrared absorber. A composite material of a nanocarbon material is not used for the thermal conductor 14, but a nanostructure such as several layers of graphene or a carbon nanotube (CNT) is used for the thermal conductor 14.

With the above configuration, in the thermoelectric conversion element 10, the nanostructure such as the several layers of graphene or the CNT has a small volume, density, and specific heat, and thus it is possible to increase the thermal resistance and decrease the thermal capacity. Moreover, since the thermal conductor 14 has a low infrared absorption rate, the thermal conductor 14 is difficult to be heated, and it is possible to obtain a large temperature difference between the hot point electrode 12 and the cold point electrode 13.

In the thermoelectric conversion element 10, since the graphene nanoribbon is used for the thermal conductor 14, the thermal resistance becomes large, and it is possible to obtain a large temperature difference between the hot point electrode and the cold point electrode. Therefore, it is possible to improve the detection sensitivity. Further, by providing the infrared absorption film 15 as a heating portion, it is possible to sufficiently heat the hot point electrode, thereby improving the detection sensitivity. Further, by forming the thermal conductor 14 in a hollow structure, it is possible to prevent the diffusion of heat and improve the detection sensitivity. Furthermore, by using the thermal conductor 14 with a very small volume, it is possible to reduce the thermal capacity and increase the response speed.

As described above, the thermoelectric conversion element 10 according to the present embodiment is formed in a structure in which the hot point electrode 12 and the cold point electrode 13 are connected to each other by the thermal conductor 24 that contains the nanostructure and the absorption film 15 that absorbs the incident light is formed on the front surface of the hot point electrode 12, and thus it is possible to achieve both high sensitivity and high speed response. In the thermoelectric conversion element 10, the thermal conductor 14 is provided at a position separated from the substrate 11, and thus the temperature difference between the hot point electrode 12 and the cold point electrode 13 is further increased compared to the case where the thermal conductor 14 is not separated therefrom. Therefore, this structure is more preferable.

### (3) Configuration of Thermoelectric Conversion Element 20 of Modification Example

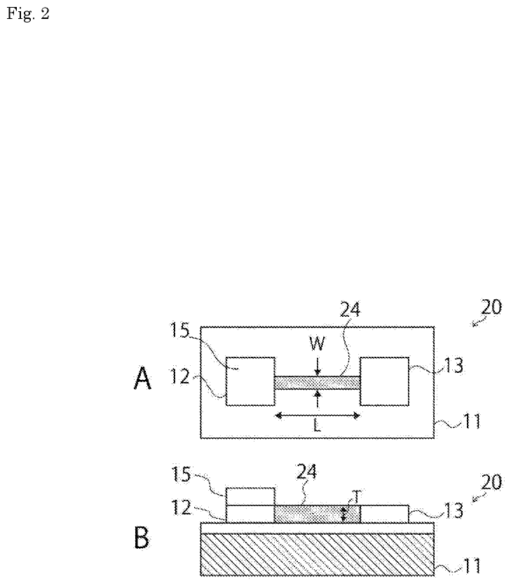

Next, a modification example of the thermoelectric conversion element 10 will be described with reference to FIG. 2. FIG. 2 is a schematic view showing the modification example of the thermoelectric conversion element 10 according to the present embodiment. In a thermoelectric conversion element 20 according to the modification example of the present embodiment, the shape of the thermal conductor is different from that of the thermoelectric conversion element 10, and other configurations are the same as those of the thermoelectric conversion element 10.

As shown in FIG. 2, the thermoelectric conversion element 20 includes a substrate 11, a hot point electrode 12 as a first electrode on a high temperature side which is disposed on a front surface of the substrate 11, a cold point electrode 13 as a second electrode on a low temperature side which is disposed on a front surface of the substrate 11, a thermal conductor 24 which connects the hot point electrode 12 and the cold point electrode 13 to each other and contains a nanostructure, and an absorption film 15 which is formed on a front surface of the hot point electrode 12 and absorbs incident light.

The thermal conductor 24 is provided between the hot point electrode 12 and the cold point electrode 13 at a position on the substrate 11 with the same height as the hot point electrode 12 and the cold point electrode 13. In addition, the planar width of the thermal conductor 24 is the same as the planar width of the thermal conductor 14.

The thermoelectric conversion element 20 according to the present modification example is formed in a structure in which the hot point electrode 12 and the cold point electrode 13 are connected to each other by the thermal conductor 24 that contains the nanostructure and the absorption film 15 that absorbs the incident light is formed on the front surface of the hot point electrode 12, and thus it is possible to achieve both high sensitivity and high speed response.

### (4) Examples of Thermoelectric Conversion Element 10

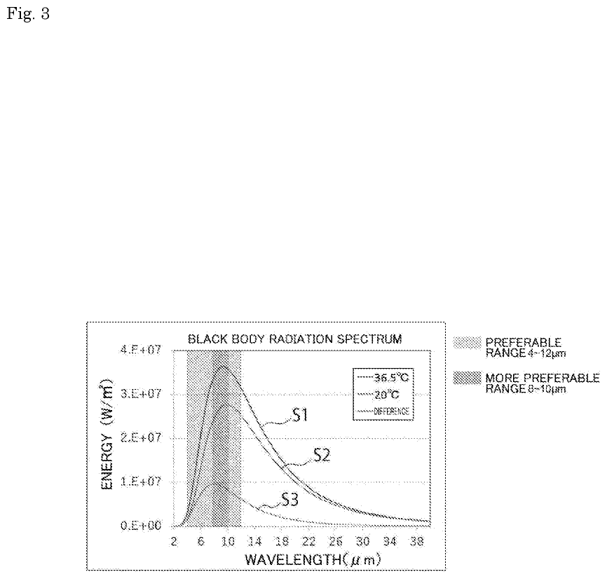

Next, examples of the thermoelectric conversion element 10 will be described with reference to FIGS. 3 to 8. The thermoelectric conversion element 10 can be applied to a thermoelectric conversion type infrared sensor, a thermoelectric conversion infrared image sensor, or the like.

The thermoelectric conversion element 10 can be applied to a thermoelectric conversion type infrared sensor or the like that enables high sensitivity and high speed response. In this infrared sensor, a plurality of thermoelectric conversion elements 10 are disposed in an array. Here, the infrared sensor capable of high sensitivity and high speed response is an infrared sensor that detects a slight temperature change at a high speed wherein a body temperature of a person is detected with an accuracy of 0.05° C. interval and operates at 240 Hz, which is four times the frame rate of the existing infrared sensor of 60 Hz.

Further, the thermoelectric conversion element 10 can be applied to a thermoelectric conversion type infrared image sensor, or the like. In this infrared image sensor, a plurality of thermoelectric conversion elements 10 are disposed in a two-dimensional array. Here, the infrared image sensor is one in which the area of one pixel is miniaturized to 100 μm 2 or less in addition to the above infrared sensor.

When the thermoelectric conversion element 10 is applied, an infrared image sensor that is smaller, consumes less power, and has higher performance than the conventional one can be obtained. In addition, the infrared image sensor can detect the physical condition, the comfort, and the emotion of a person from information such as a temperature change in a body temperature of the person in minute time and temperature distribution in the face, the hands, the body, the feet, or the like of the person.

In addition, a plurality of thermoelectric conversion elements 10 are used to form a thermoelectric conversion element array in which the material of the thermal conductor 14 is a carbon material and the thermoelectric conversion elements 10 are connected to each other by a metal having a different polarity of thermoelectric performance from the carbon material.

A preferred range of an infrared absorption wavelength of the thermoelectric conversion element 10 according to the present embodiment will be described with reference to FIG. 3. FIG. 3 is a graph showing the range of the infrared absorption wavelength of the thermoelectric conversion element 10. In FIG. 3, a horizontal axis indicates a wavelength (μm), and a vertical axis indicates energy (W/m²).

A curve S1 in FIG. 3 represents a black body radiation spectrum emitted in a case where a body temperature of a person is 36.5° C., and a curve S2 represents a black body radiation spectrum emitted in a case where a body temperature of a person is 20° C. A curve S3 in FIG. 3 represents a difference between the black body radiation spectrum of the curve S1 and the black body radiation spectrum of the curve S2.

As shown in FIG. 3, the range of the infrared absorption wavelength range is preferably 4 to 12 μm, which is a peak position of an infrared spectrum emitted from a body temperature of a person. The range of the infrared absorption wavelength range is more preferably 8 to 10 μm, which is a peak position of an infrared spectrum emitted from a body temperature of a person.

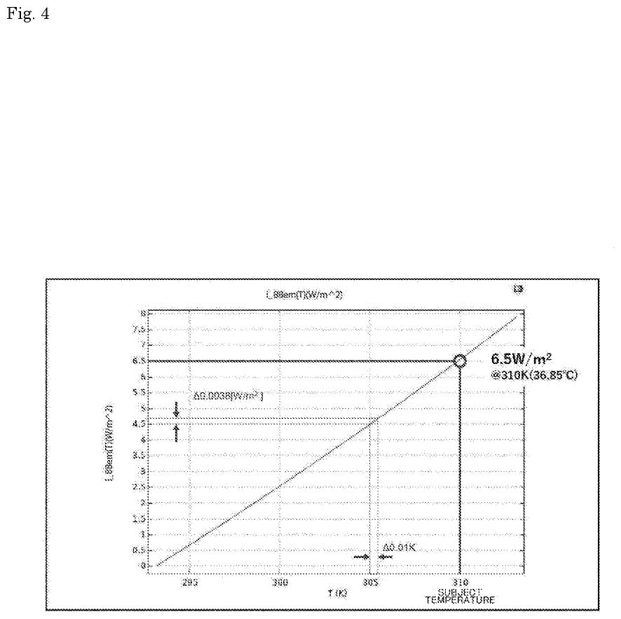

Next, the amount of infrared light detected by the thermoelectric conversion element 10 will be described with reference to FIG. 4. FIG. 4 is a graph showing the amount of infrared light detected by the thermoelectric conversion element 10. In FIG. 4, a horizontal axis indicates room temperature (K), and a vertical axis indicates energy (W/m²).

As shown in FIG. 4, the maximum amount of light from a black body (a body temperature of a person: 310 K) which can be detected by the infrared sensor at room temperature (293.15 K) is 6.5 W/m². A black body light amount difference due to a temperature difference of 0.05 K is 6.5/{(310−293.15)/0.05}=0.019 W/m². If the frame rate is 240 Hz, (1 frame rate·optical energy per unit area)=1.6e⁻⁵ J/m².

Therefore, from the requirements of a sensor circuit, a voltage output from the sensor must be 10 μV or more at a black body light amount difference of 0.019 W/m². In order to detect an output voltage of 10 μV or more, a light receiving area must be enlarged, but in a case where the thermal resistance is used as a variable, the thermal resistance of the thermal conductor 14 is preferably 2.5×10⁷ K/W or more.

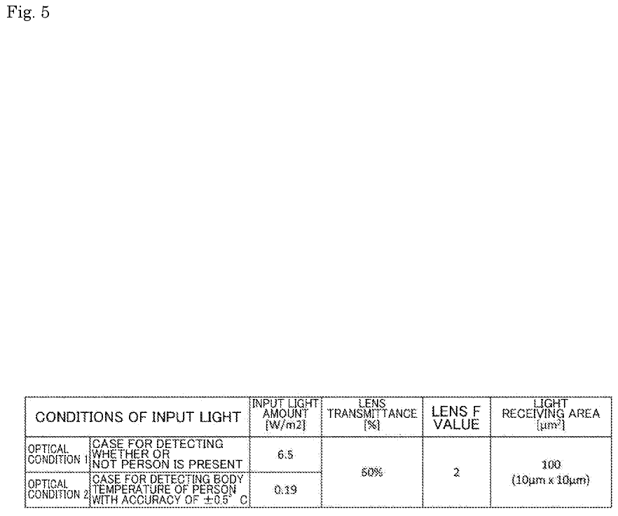

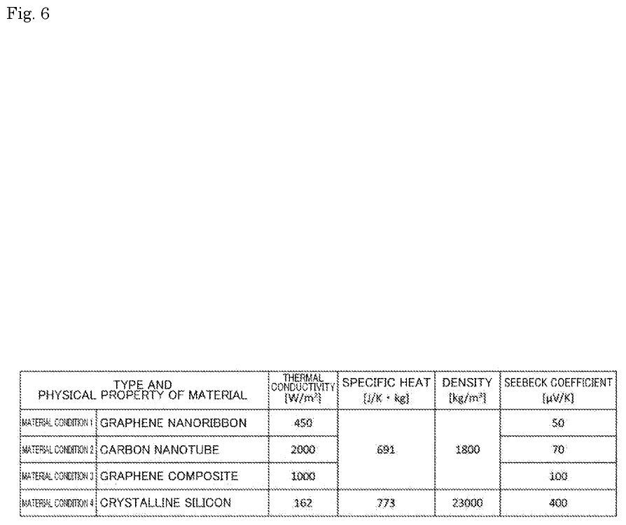

Next, optical conditions of incident light (input light) and material conditions applied to the thermoelectric conversion element 10 will be described with reference to FIGS. 5 and 6. FIG. 5 is a table showing optical conditions of incident light used for the thermoelectric conversion element 10. FIG. 6 is a table showing material conditions used for the thermal conductor 14 of the thermoelectric conversion element 10. FIG. 6 is extracted from “COMSOL Multiphysics Materials Database” or “MST Distributed Thermophysical Properties Database (TPDS-web)”.

As shown in FIG. 5, in the thermoelectric conversion element 10, for example, when a light receiving area is 100 μm², an F value of a lens is 2, and a lens transmittance is 60%, an input light amount used for detecting whether or not a person is present is preferably 6.5 W/m² (Optical Condition 1). Further, the input light amount used for detecting a body temperature of a person with an accuracy of ±0.5° C. is preferably 0.19 W/m² (Optical Condition 2). On the other hand, as shown in FIG. 6, in the case of Material Condition 1 using a graphene nanoribbon for the thermal conductor 14 of the thermoelectric conversion element 10, compared to Material Condition 2 using a carbon nanotube and Material Condition 3 using a graphene composite, since a cross-sectional area (width W×thickness T) of the thermal conductor 14 in a heat transfer direction can be made extremely small, the thermal conductivity is low and the thermal resistance is large, and thus it is possible to realize high sensitivity.

In addition, in the case of Material Condition 1, compared to the case of Material Condition 4 using crystalline silicon, since carbon with a very low density is used as a material and the thickness is thin, the volume can be reduced, and thus it is possible to reduce the thermal capacity. As a result, in the case of Material Condition 1, it is possible to realize the thermoelectric conversion element 10 and the thermoelectric conversion type infrared sensor that achieve both high sensitivity and high speed response, which have not been possible in the related art.

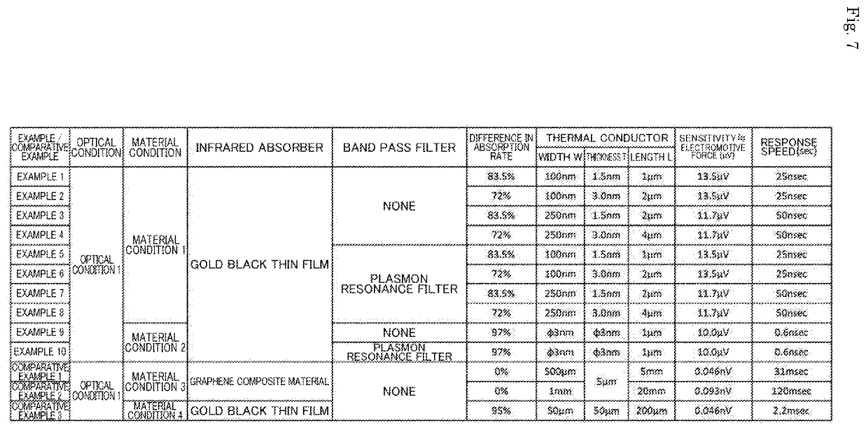

Next, examples and comparative examples of the thermoelectric conversion element 10 will be described with reference to FIG. 7. FIG. 7 is a table showing the examples and the comparative examples of the thermoelectric conversion element 10. Here, in order to realize a sensor with a frame rate of 240 Hz, which can be said to be a high speed response, it is desirable that the time constant (the response speed) τ of thermal response be 4 msec or less.

As shown in FIG. 7, in Examples 1 to 8, Optical Condition 1 in FIG. 5 and Material Condition 1 in FIG. 6 are used, and a gold black thin film is used for the infrared absorber (the infrared absorption film) 15. As a result, the difference in infrared absorption rate between the absorption film 15 and the thermal conductor 14 is 70% or more (72% or 83.5%). As a result, the electromotive force is 10 μV or more (11.7 μV or 13.5 μV) and the response speed is 50 nsec or less (50 nsec or 25 nsec), and thus it is possible to realize both high sensitivity and high speed response.

Further, in Examples 9 to 10, Optical Condition 1 in FIG. 5 and Material Condition 2 in FIG. 6 are used, and a gold black thin film is used for the infrared absorber 15. As a result, the difference in infrared absorption rate between the absorption film 15 and the thermal conductor 14 is 97%. As a result, the electromotive force is 10 μV and the response speed is 0.6 nsec, and thus it is possible to realize both high sensitivity and high speed response.

On the other hand, in Comparative Examples 1 and 2, the difference in infrared absorption rate between the absorption film and the thermal conductor due to the combination of the absorption film and the thermal conductor is 0% and less than 60%, the electromotive force is 0.1 nV or less, and the response speed is 30 msec or more. In Comparative Example 3, the difference in infrared absorption rate between the absorption film and the thermal conductor is 95%, and the response speed is 2.2 msec, but the electromotive force is 0.046 nV. Therefore, in Comparative Examples 1 to 3, it is not possible to realize both high sensitivity and high speed response.

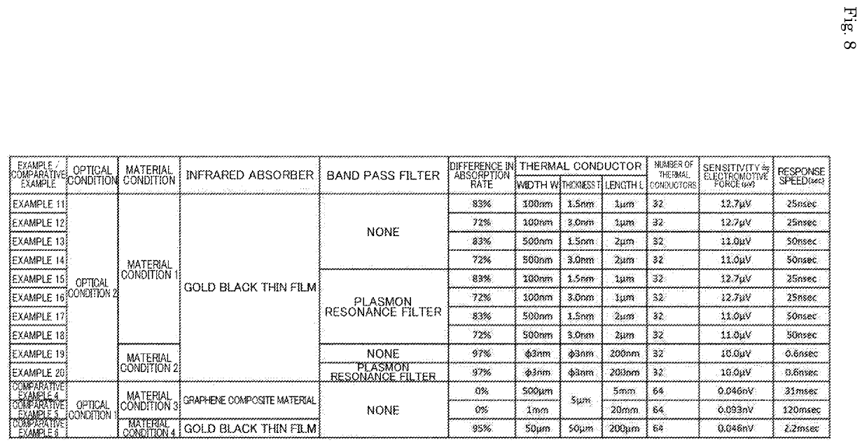

Next, examples and comparative examples of the infrared sensor using the thermoelectric conversion element 10 will be described with reference to FIG. 8. FIG. 8 is a table showing the examples and the comparative examples of the infrared sensor using the thermoelectric conversion element 10.

As shown in FIG. 8, in Examples 11 to 18, Optical Condition 2 in FIG. 5 and Material Condition 1 in FIG. 6 are used, and a gold black thin film is used for the infrared absorber 15. As a result, the difference in infrared absorption rate between the absorption film 15 and the thermal conductor 14 is 70% or more (72% or 83%). As a result, the electromotive force is 10 μV or more (11.0 μV or 12.7 μV) and the response speed is 50 nsec or less (50 nsec or 25 nsec), and thus it is possible to realize both high sensitivity and high speed response.

Further, in Examples 19 and 20, Optical Condition 2 in FIG. 5 and Material Condition 2 in FIG. 6 are used, and a gold black thin film is used for the infrared absorber 15. As a result, the difference in infrared absorption rate between the absorption film 15 and the thermal conductor 14 is 97%. As a result, the electromotive force is 10 μV and the response speed is 0.6 nsec, and thus it is possible to realize both high sensitivity and high speed response.

On the other hand, in Comparative Examples 4 and 5, the difference in infrared absorption rate between the absorption film and the thermal conductor due to the combination of the absorption film and the thermal conductor is 0% and less than 60%, the electromotive force is 0.1 nV or less, and the response speed is 30 msec or more. In Comparative Example 6, the difference in infrared absorption rate between the absorption film and the thermal conductor is 95%, and the response speed is 2.2 msec, but the electromotive force is 0.046 nV. Therefore, in Comparative Examples 4 to 6, it is not possible to realize both high sensitivity and high speed response.

### (5) Configuration Example of Heat Collection Structure

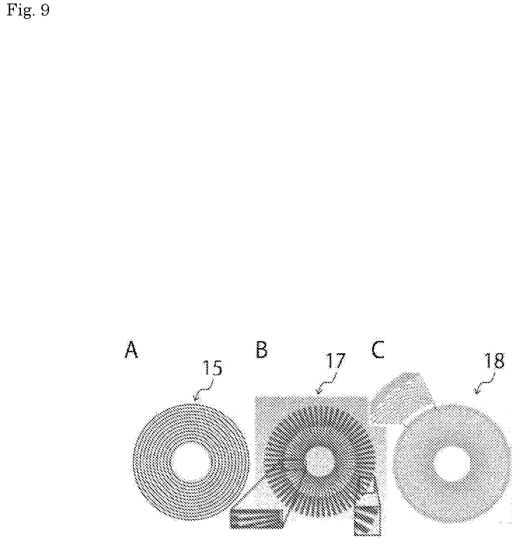

Next, examples of a heat collection structure provided on the front surface of the absorption film 15 included in the thermoelectric conversion element 10 will be described with reference to FIG. 9. FIGS. 9A to 9C are plan views showing the examples of the heat collection structure provided on the front surface of the absorption film 15.

A heat collection structure 16 shown in FIG. 9A has a circular shape in overall shape, and a plurality of concentric circles are formed within the circular shape. Such a shape allows the heat collection structure 16 to concentrate heat in the center of the circular shape compared to the periphery.

A heat collection structure 17 shown in FIG. 9B has a circular shape in overall shape, and a plurality of minute fan shapes are arranged from the circumference toward the center of the circular shape. Such a shape allows the heat collection structure 17 to concentrate more heat in the center of the circular shape than the heat collection structure 16.

The heat collection structure 18 shown in FIG. 9C has a circular shape in overall shape and is spirally formed from the vicinity of the circumference toward the center of the circular shape. Such a shape allows the heat collection structure 17 to concentrate heat over the entire circular shape and in particular, to concentrate more heat in the center of the circular shape than the heat collection structure 16.

### 2. Second Embodiment

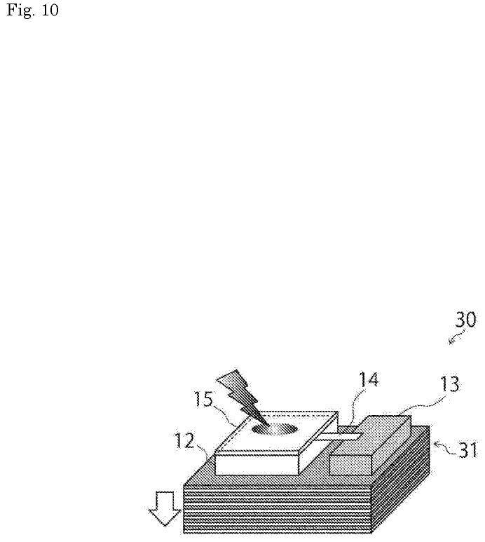

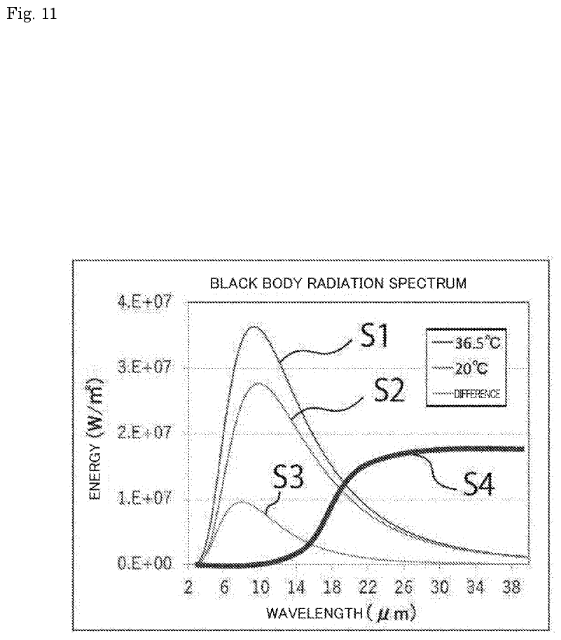

Next, a configuration example of a thermoelectric conversion element 30 according to a second embodiment of the present technology will be described with reference to FIGS. 10 and 11. FIG. 10 is a schematic view showing the configuration example of the thermoelectric conversion element 30 according to the present embodiment. In the thermoelectric conversion element 30, the structure of the substrate is different from that of the thermoelectric conversion element 10 according to the first embodiment, and other configurations are the same as those of the thermoelectric conversion element 10.

As shown in FIG. 10, the thermoelectric conversion element 30 includes a substrate 31, a hot point electrode 12 as a first electrode on a high temperature side which is disposed on a front surface of the substrate 31, a cold point electrode 13 as a second electrode on a low temperature side which is disposed on a front surface of the substrate 31, a thermal conductor 14 which connects the hot point electrode 12 and the cold point electrode 13 to each other and contains a nanostructure, and an absorption film 15 which is formed on a front surface of the hot point electrode 12 and absorbs incident light.

The substrate 31 is formed of a multilayer film of thermal resonance reflection films having different specific heats. The thermoelectric conversion element 30 includes the substrate 31 that forms a thermal AR film structure with the multilayer film having different specific heats and thus can curb heat dissipation.

FIG. 11 is a graph showing a resonance absorption spectrum of the thermoelectric conversion element 30. In FIG. 11, a horizontal axis indicates a wavelength (μm), and a vertical axis indicates energy (W/m²).

A curve S1 in FIG. 11 represents a black body radiation spectrum emitted in a case where a body temperature of a person is 36.5° C., and a curve S2 represents a black body radiation spectrum emitted in a case where a body temperature of a person is 20° C. A curve S3 in FIG. 11 represents a difference between the black body radiation spectrum of the curve S1 and the black body radiation spectrum of the curve S2. Further, a curve S4 in FIG. 11 represents a resonance absorption spectrum in a case where plasmon resonance of the thermoelectric conversion element 30 is used.

As shown in FIG. 11, in the thermoelectric conversion element 30, a peak of a resonance absorption spectrum of the curve S4 is shifted from peak positions of the black body radiation spectrums of the curves S1 and S2 which are sensed, it is possible to curb heat absorption due to the infrared ray.

As described above, in the thermoelectric conversion element 30 of the present embodiment, similarly to the thermoelectric conversion element 10 according to the first embodiment, it is possible to realize both high sensitivity and high speed response.

### 3. Third Embodiment

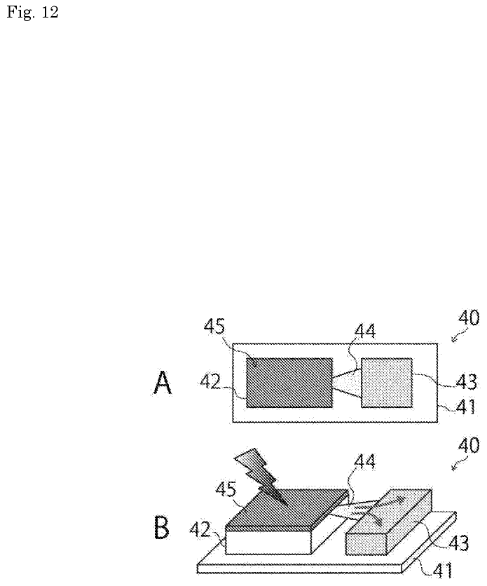

Next, a configuration example of a thermoelectric conversion element 40 according to a third embodiment of the present technology will be described with reference to FIG. 12. FIG. 12 is a schematic view showing the configuration example of the thermoelectric conversion element 40 according to the present embodiment. In the thermoelectric conversion element 40, the structure of the thermal conductor is different from that of the thermoelectric conversion element 10 according to the first embodiment, and other configurations are the same as those of the thermoelectric conversion element 10.

As shown in FIG. 12, the thermoelectric conversion element 40 includes a substrate 41, a hot point electrode 42 as a first electrode on a high temperature side which is disposed on a front surface of the substrate 41, a cold point electrode 43 as a second electrode on a low temperature side which is disposed on a front surface of the substrate 41, a thermal conductor 44 which connects the hot point electrode 42 and the cold point electrode 43 to each other and contains a nanostructure, and an absorption film 45 which is formed on a front surface of the hot point electrode 42 and absorbs incident light.

The thermal conductor 44 is provided at a position separated from the substrate 41 and connects the hot point electrode 12 and the cold point electrode 13 to each other in a shape of a beam that serves as a hollow structure. Further, the width of the thermal conductor 44 increases from the hot point electrode 12 toward the cold point electrode 13.

In the thermoelectric conversion element 40, since the width of the thermal conductor 44 is formed to increase from the hot point electrode 12 toward the cold point electrode 13, the heat is diffused, and the temperature difference between the hot point electrode 12 and the cold point electrode 13 can be increased. Therefore, in the thermoelectric conversion element 40 of the present embodiment, similarly to the thermoelectric conversion element 10 according to the first embodiment, it is possible to realize both high sensitivity and high speed response.

The thermal conductor 44 may be provided with a structure such as a diode that allows heat to flow only in one direction. As a result, the thermal resistance of the thermal conductor 44 can be increased and the thermal conductivity can be decreased.

### 4. Fourth Embodiment

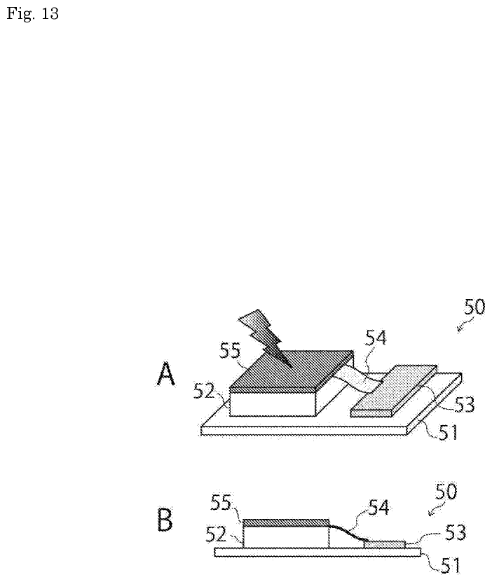

Next, a configuration example of a thermoelectric conversion element 50 according to a fourth embodiment of the present technology will be described with reference to FIG. 13. FIG. 13 is a schematic view showing the configuration example of the thermoelectric conversion element 50 according to the present embodiment. FIG. 13A is a perspective view of the thermoelectric conversion element 50, and FIG. 13B is a side view of the thermoelectric conversion element 50. In the thermoelectric conversion element 50, the structures of the first electrode, the second electrode, and the thermal conductor are different from those of the thermoelectric conversion element 10 according to the first embodiment, and other configurations are the same as those of the thermoelectric conversion element 10.

As shown in FIGS. 13A and 13B, the thermoelectric conversion element 50 includes a substrate 51, a hot point electrode 52 as a first electrode on a high temperature side which is disposed on a front surface of the substrate 51, a cold point electrode 53 as a second electrode on a low temperature side which is disposed on a front surface of the substrate 51, a thermal conductor 54 which connects the hot point electrode 52 and the cold point electrode 53 to each other and contains a nanostructure, and an absorption film 55 which is formed on a front surface of the hot point electrode 52 and absorbs incident light.

In the present embodiment, as an example, the hot point electrode 52 is formed thicker than the cold point electrode 13. However, it is sufficient for the hot point electrode 52 and the cold point electrode 13 have different thicknesses, and the cold point electrode 13 may be formed thicker than the hot point electrode 52.

The thermal conductor 54 is provided at a position separated from the substrate 51 and connects the hot point electrode 12 and the cold point electrode 13 to each other in a shape of a beam that serves as a hollow structure. Furthermore, the thermal conductor 54 is bent between the hot point electrode 12 and the cold point electrode 13 to provide curvature.

In the thermoelectric conversion element 50, the thermal conductivity of the thermal conductor 54 can be lowered by bending the thermal conductor 54 to provide the curvature. Therefore, in the thermoelectric conversion element 50 of the present embodiment, similarly to the thermoelectric conversion element 10 according to the first embodiment, it is possible to realize both high sensitivity and high speed response.

### 5. Example of Method for Manufacturing Photothermoelectric Conversion Element

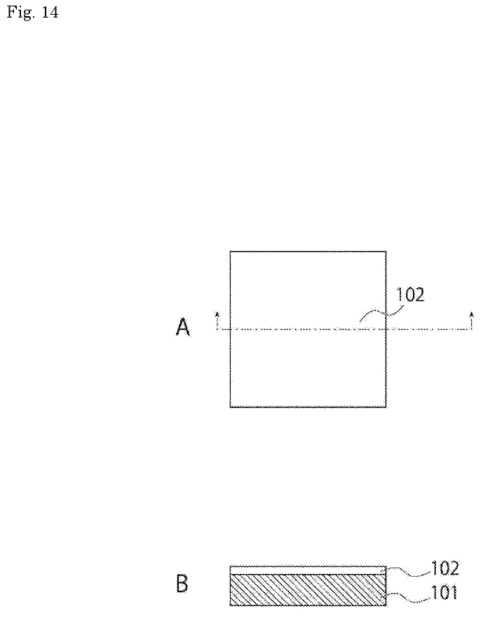

Next, an example of a method for manufacturing a photothermoelectric conversion element according to the present technology will be described with reference to FIGS. 14 to 25. FIGS. 14 to 25 are schematic views showing an example of the method for manufacturing a photothermoelectric conversion element according to the present technology. Each of FIGS. 14A to 25A shows a plan view of the photothermoelectric conversion element in a manufacturing process. Each of FIGS. 14B to 25B shows a cross-sectional view of the photothermoelectric conversion element in a manufacturing process at the center position in a vertical direction of each of FIGS. 14A to 25A.

According to the present manufacturing method, a photothermoelectric conversion element that includes a pair of hot point electrode and cold point electrode, a thermal conductor connecting the electrodes to each other, and an infrared absorption film having a large area on the hot point electrode is manufactured.

As a first step, as shown in FIGS. 14A and 14B, a sample Si substrate 101 is cleaned. Specifically, the Si substrate 101 with a thermally oxidized SiO₂ film 102 having a thickness of 300 nm is prepared. The prepared Si substrate 101 is cut into 20 mm squares with a scriber. The cut Si substrate 101 is ultrasonically cleaned with acetone, isopropyl alcohol, and water in that order for 10 minutes each. It is then dried using dry air to remove water.

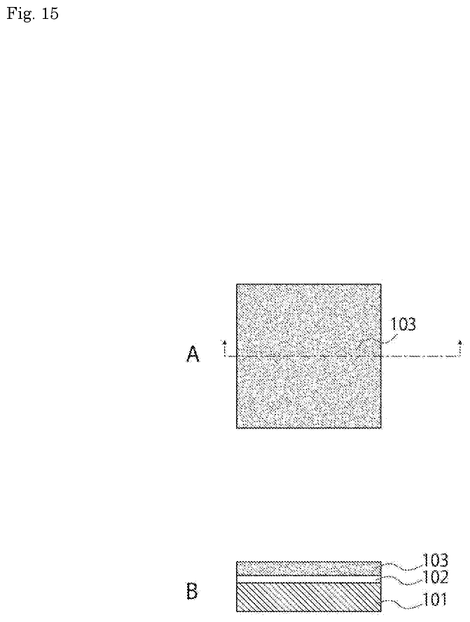

As a second step, as shown in FIGS. 15A and 15B, a silicon nitride film (a SiNx film) 103 is formed. Specifically, the prepared Si substrate 101 with the SiO₂ film 102 is set in a plasma CVD apparatus manufactured by SAMCO Inc., and the pressure is reduced to 10⁻⁵ Pa. SN₂ as a source gas and N₂ as a carrier gas are introduced into a CVD chamber, and the SiNx film 103 is formed at a film formation rate of 0.8 nm/sec for 625 seconds. After the formation of the SiNx film 103 is completed, the sample Si substrate 101 is taken out, and the film thickness thereof is measured using Ellipsometry manufactured by Horiba, Ltd., wherein it is confirmed that the SiNx film 103 of 500 nm is formed.

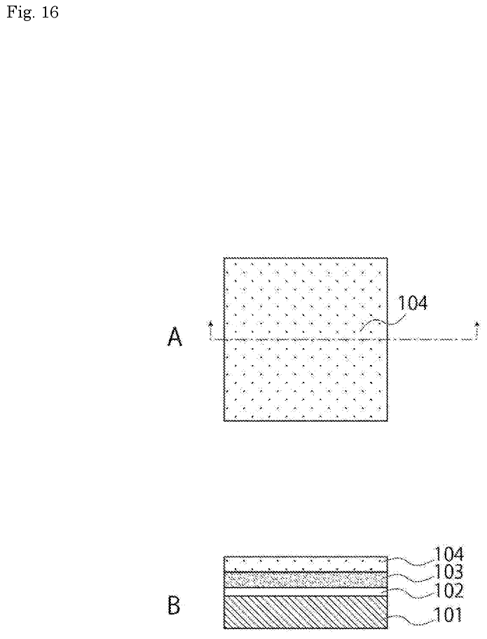

As a third step, as shown in FIGS. 16A and 16B, a PMMA resist 1 for electron beam drawing is formed. Specifically, the sample Si substrate 101 is coated with an 8% toluene solution of PMMA manufactured by Microchem Corp., and a film is formed in a spin-coating manner at 3000 rpm for 30 seconds using a spin coater manufactured by MIKASA Corp. A formed PMMA film 104 is heated by a hot plate at 150° C. for 120 seconds to be dried.

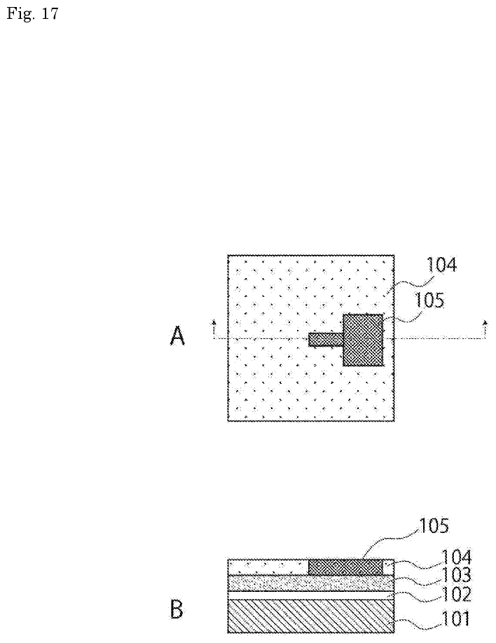

As a fourth step, as shown in FIGS. 17A and 17B, Patterning 1 of an exposed portion (a PMMA film) 105 that will become the thermal conductor and the cold point electrode is performed. Specifically, the sample Si substrate 101 is set in an electron beam drawing apparatus manufactured by ELIONIX Inc., and a pattern as shown in FIG. 17A is drawn with an electron beam. Electron beam drawing conditions are exposure conditions of an acceleration voltage of 130 kV, a current value of 100 pA, and a dose of 250 μC/m². The thermal conductor has a width of 20 nm to 100 nm and a length of 1 to 10 μm. The cold point electrode has a size of about 20 μm×50 μm.

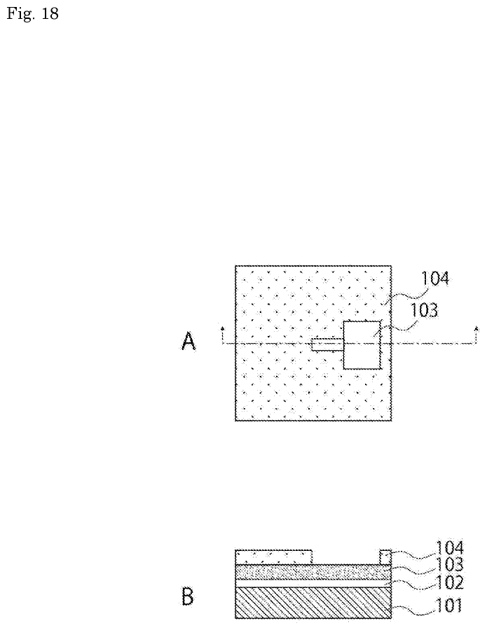

As a fifth step, as shown in FIGS. 18A and 18B, Patterning 2 of the thermal conductor and the cold point electrode is performed. Specifically, after electron beam drawing is completed, the sample Si substrate 101 is taken out and immersed in a 3:1 solution of methyl isobutyl ketone (MIBK) and isopropyl alcohol (IPA) for 60 seconds for performing development.

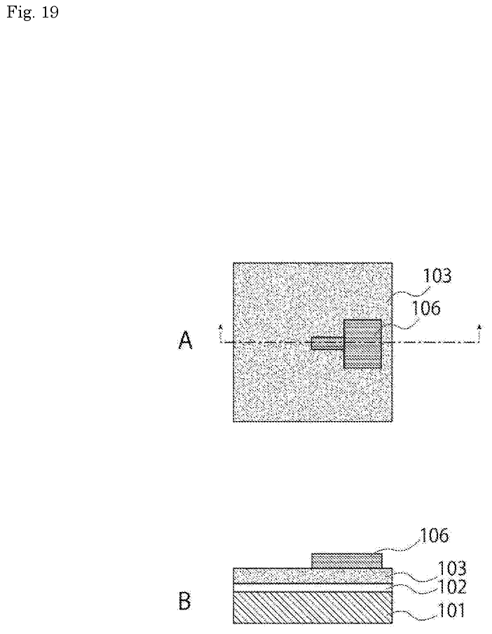

As a sixth step, as shown in FIGS. 19A and 19B, Patterning 3 of the thermal conductor and the cold point electrode is performed. Specifically, after the development, a film of a nickel metal 106 is formed to be 50 nm at 1 Å/sec using an electron beam heating evaporator manufactured by EIKO Co., Ltd. After the film of the nickel metal 106 is formed, the sample Si substrate 101 is taken out, immersed in an acetone solution for 600 seconds, and lifted off with an ultrasonic cleaner to complete the patterning of the thermal conductor and the cold point electrode.

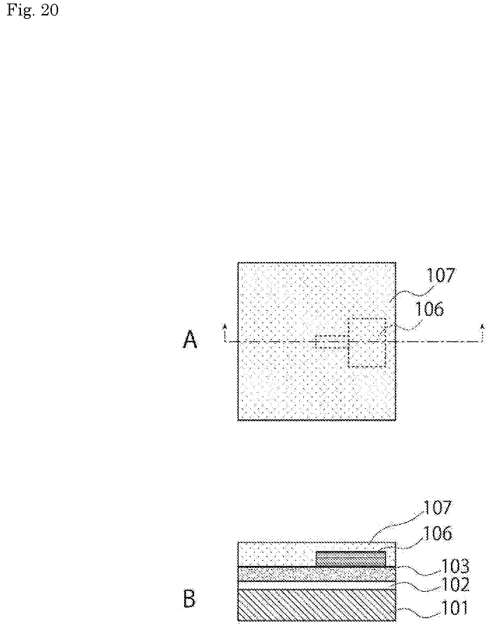

As a seventh step, as shown in FIGS. 20A and 20B, a PMMA resist 2 for electron beam drawing is formed. Specifically, the sample Si substrate 101 is coated with an 8% toluene solution of PMMA manufactured by Microchem Corp., and a film is formed in a spin-coating manner at 3000 rpm for 30 seconds using a spin coater manufactured by MIKASA Corp. A formed PMMA film 107 is heated by a hot plate at 150° C. for 120 seconds to be dried.

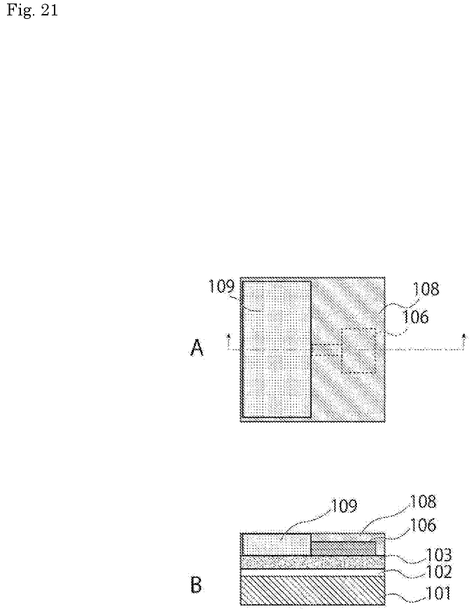

As an eighth step, as shown in FIGS. 21A and 21B, Patterning 1 of an exposed portion (a PMMA film) 109 that will become the hot point electrode is performed. Specifically, the sample Si substrate 101 is set in an electron beam drawing apparatus manufactured by ELIONIX Inc., and a pattern as shown in FIG. 21A is drawn with an electron beam. Electron beam drawing conditions are exposure conditions of an acceleration voltage of 130 kV, a current value of 100 pA, and a dose of 250 μC/m². The hot point electrode has a size of about 2 mm×1 mm.

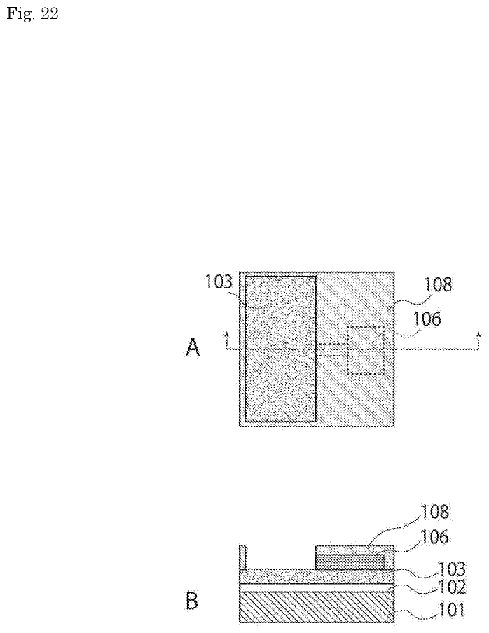

As a ninth step, as shown in FIGS. 22A and 22B, Patterning 2 of the hot point electrode is performed. Specifically, after electron beam drawing is completed, the sample Si substrate 101 is taken out and immersed in a 3:1 solution of methyl isobutyl ketone (MIBK) and isopropyl alcohol (IPA) for 60 seconds for performing development.

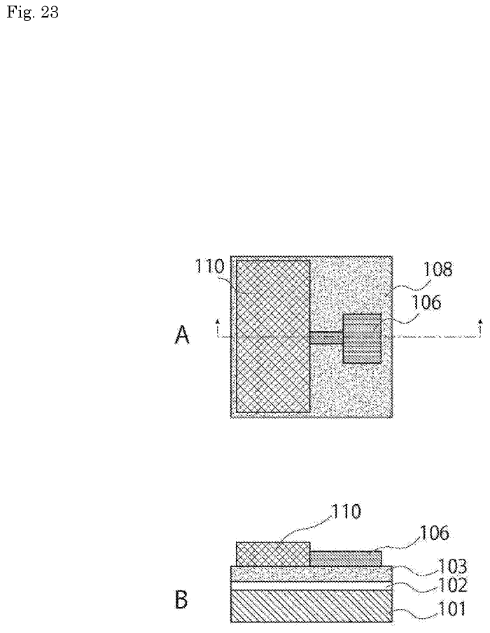

As a tenth step, as shown in FIGS. 23A and 23B, Patterning 3 of the hot point electrode is performed. Specifically, after the development, a film of a platinum metal 110 that will become the hot point electrode is formed to be 100 nm at 1 Å/sec using an electron beam heating evaporator manufactured by EIKO Co., Ltd. After the film of the platinum metal 110 is formed, the sample Si substrate 101 is taken out, immersed in an acetone solution for 600 seconds, and lifted off with an ultrasonic cleaner to complete the patterning of the hot point electrode.

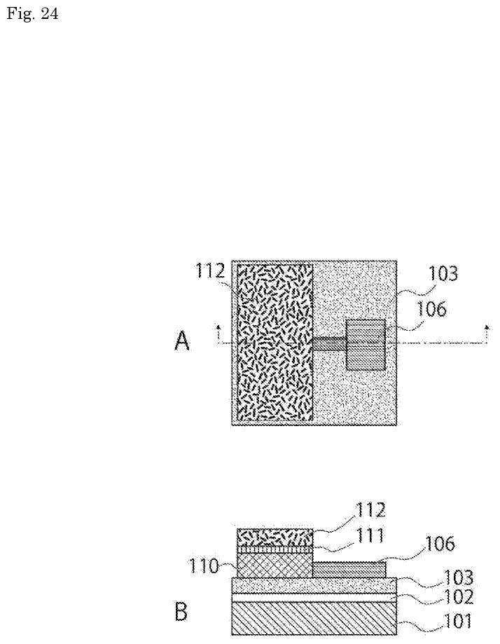

As an eleventh step, as shown in FIGS. 24A and 24B, an infrared absorption film 112 is formed. Specifically, a parylene or polyimide precursor, which is an insulating film 111, is vapor-deposited by resistance heating on the platinum metal 110 through metal mask vapor deposition. After that, the sample Si substrate 101 is set in a resistance heating type vacuum evaporator. A leak valve of the vacuum evaporator is adjusted, a degree of vacuum of the vacuum evaporator is adjusted to 100 Pa, and a film of gold set in a tungsten boat in advance is formed to be 100 nm. The obtained vapor deposition film becomes the infrared absorption film 112 called Gold Black, which has a very good absorption rate of 99.7% in the wavelength range from 400 nm in a visible region to 13 μm in a mid-infrared region.

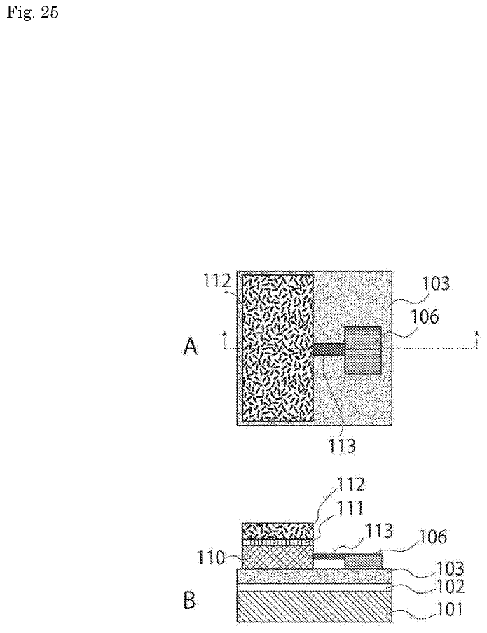

As a twelfth step, as shown in FIGS. 25A and 25B, a film of a thermal conductor (a graphene nanoribbon) 113 is formed. Specifically, the sample Si substrate 101 is set in the plasma CVD apparatus, and the pressure is reduced to 10⁻⁵ Pa. Argon as a carrier gas and methane (CH₄) as a process gas are introduced into the CVD apparatus and stand until the degree of vacuum is stabilized. When the degree of vacuum is stabilized, a plasma emitting device is set, and plasma emitting is performed for 18 seconds from the outside of the vacuum chamber. After the carrier gas and the process gas are stopped, and the pressure inside the chamber is brought to an atmospheric pressure, the sample Si substrate 101 is taken out. When observation from an oblique angle of 30 degrees is performed using a surface electron microscope (SEM), it can be confirmed that the thermal conductor 113 of a graphene nanoribbon hollow body is manufactured.

### 6. Example of Method for Manufacturing Infrared Sensor

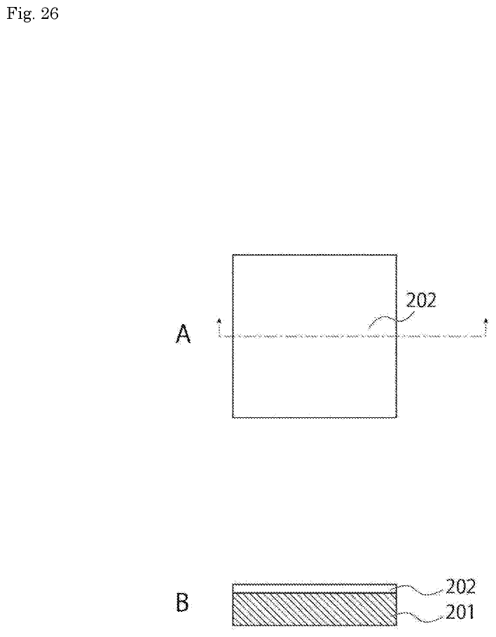

Next, an example of a method for manufacturing an infrared sensor using the thermoelectric conversion element according to the present technology will be described with reference to FIGS. 26 to 37. FIGS. 26 to 37 are schematic views showing an example of the method for manufacturing an infrared sensor using the thermoelectric conversion element according to the present technology. Each of FIGS. 26A to 37A shows a plan view of the infrared sensor in a manufacturing process. Each of FIGS. 26B to 37B shows a cross-sectional view of the infrared sensor in a manufacturing process at the center position in a vertical direction of each of FIGS. 26A to 37A.

The method for manufacturing an infrared sensor according to the present technology differs from the method for manufacturing a photothermoelectric conversion element according to the present technology in that a structure in which 16 pairs of photothermoelectric conversion elements are connected in series is formed through patterning, but is the same as the method for manufacturing a photothermoelectric conversion element according to the present technology in other processes.

As a first step, as shown in FIGS. 26A and 26B, a sample Si substrate 201 is cleaned. Specifically, the Si substrate 201 with a thermally oxidized SiO₂ film 202 having a thickness of 300 nm is prepared. The prepared Si substrate 201 is cut into 20 mm squares with a scriber. The cut Si substrate 201 is ultrasonically cleaned with acetone, isopropyl alcohol, and water in that order for 10 minutes each. It is then dried using dry air to remove water.

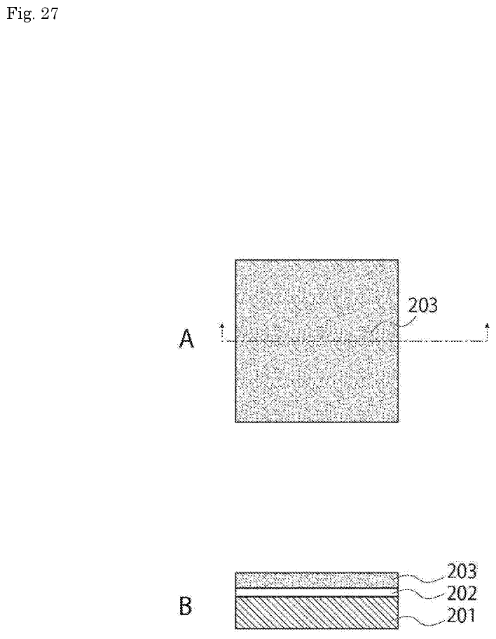

As a second step, as shown in FIGS. 27A and 27B, a silicon nitride film (a SiNx film) 103 is formed. Specifically, the prepared Si substrate 201 with the SiO₂ film 202 is set in a plasma CVD apparatus manufactured by SAMCO Inc., and the pressure is reduced to 10⁻⁵ Pa. SN₂ as a source gas and N₂ as a carrier gas are introduced into a CVD chamber, and a SiNx film 203 is formed at a film formation rate of 0.8 nm/sec for 625 seconds. After the formation of the SiNx film 203 is completed, the sample Si substrate 201 is taken out, and the film thickness thereof is measured using Ellipsometry manufactured by Horiba, Ltd., wherein it is confirmed that the SiNx film 103 of 500 nm is formed.

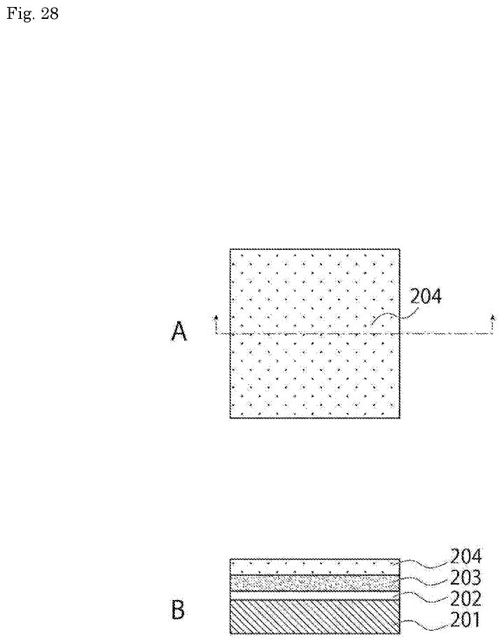

As a third step, as shown in FIGS. 28A and 28B, a PMMA resist 1 for electron beam drawing is formed. Specifically, the sample Si substrate 201 is coated with an 8% toluene solution of PMMA manufactured by Microchem Corp., and a film is formed in a spin-coating manner at 3000 rpm for 30 seconds using a spin coater manufactured by MIKASA Corp. A formed PMMA film 204 is heated by a hot plate at 150° C. for 120 seconds to be dried.

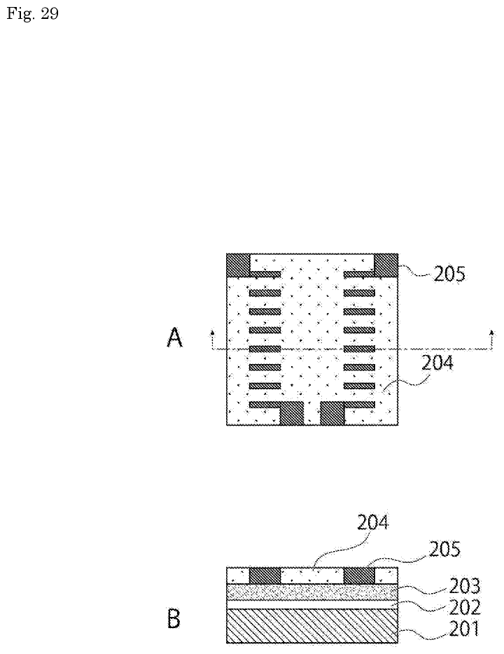

As a fourth step, as shown in FIGS. 29A and 29B, Patterning 1 of an exposed portion (a PMMA film) 105 that will become the thermal conductor and the cold point electrode is performed. Specifically, the sample Si substrate 201 is set in an electron beam drawing apparatus manufactured by ELIONIX Inc., and a pattern as shown in FIG. 29A is drawn with an electron beam. Electron beam drawing conditions are exposure conditions of an acceleration voltage of 130 kV, a current value of 100 pA, and a dose of 250 μC/m². The thermal conductor has a width of 20 nm to 100 nm and a length of 1 to 10 μm. The cold point electrode has a size of about 20 μm×50 μm.

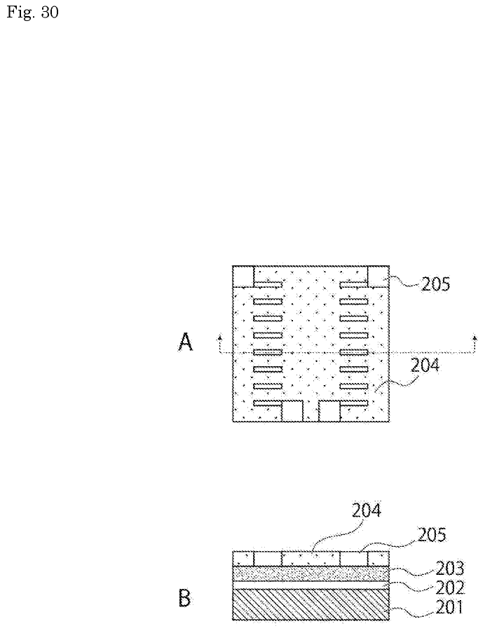

As a fifth step, as shown in FIGS. 30A and 30B, Patterning 2 of the thermal conductor and the cold point electrode is performed. Specifically, after electron beam drawing is completed, the sample Si substrate 201 is taken out and immersed in a 3:1 solution of methyl isobutyl ketone (MIBK) and isopropyl alcohol (IPA) for 60 seconds for performing development.

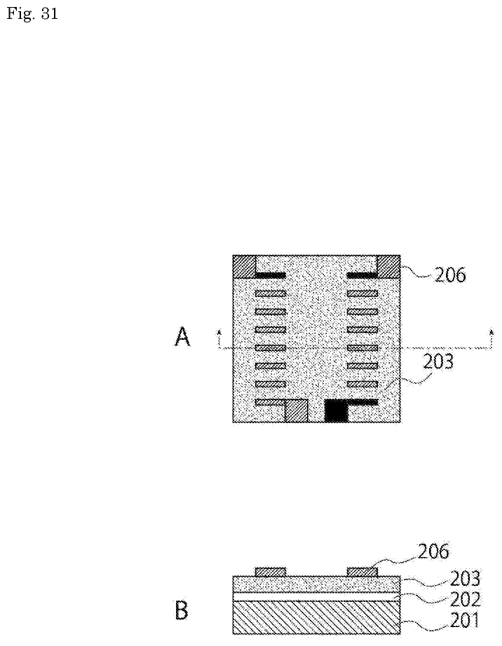

As a sixth step, as shown in FIGS. 31A and 31B, Patterning 3 of the thermal conductor and the cold point electrode is performed. Specifically, after the development, a film of a nickel metal 206 is formed to be 50 nm at 1 Å/sec using an electron beam heating evaporator manufactured by EIKO Co., Ltd. After the film of the nickel metal 206 is formed, the sample Si substrate 201 is taken out, immersed in an acetone solution for 600 seconds, and lifted off with an ultrasonic cleaner to complete the patterning of the thermal conductor and the cold point electrode.

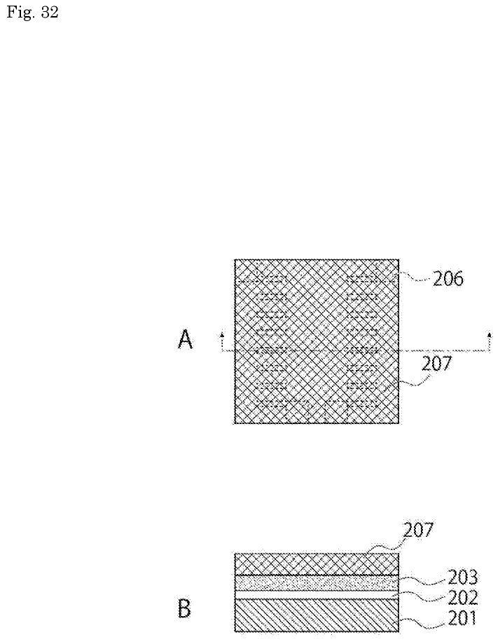

As a seventh step, as shown in FIGS. 32A and 32B, a PMMA resist 2 for electron beam drawing is formed. Specifically, the sample Si substrate 201 is coated with an 8% toluene solution of PMMA manufactured by Microchem Corp., and a film is formed in a spin-coating manner at 3000 rpm for 30 seconds using a spin coater manufactured by MIKASA Corp. A formed PMMA film 207 is heated by a hot plate at 150° C. for 120 seconds to be dried.

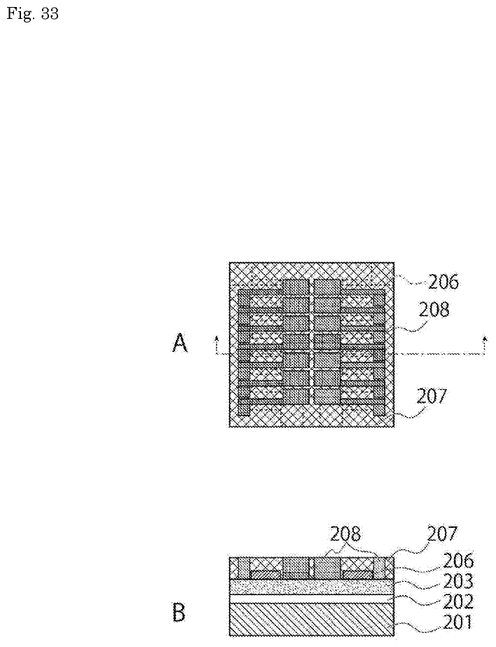

As an eighth step, as shown in FIGS. 33A and 33B, Patterning 1 of an exposed portion (a PMMA film) 208 that will become the hot point electrode is performed. Specifically, the sample Si substrate 201 is set in an electron beam drawing apparatus manufactured by ELIONIX Inc., and a pattern as shown in FIG. 33A is drawn with an electron beam. Electron beam drawing conditions are exposure conditions of an acceleration voltage of 130 kV, a current value of 100 pA, and a dose of 250 μC/m². The hot point electrode has a size of about 2 mm×1 mm.

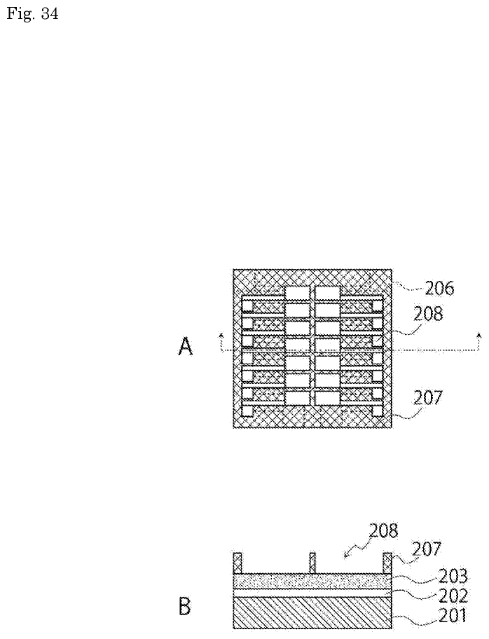

As a ninth step, as shown in FIGS. 34A and 34B, Patterning 2 of the hot point electrode is performed. Specifically, after electron beam drawing is completed, the sample Si substrate 201 is taken out and immersed in a 3:1 solution of methyl isobutyl ketone (MIBK) and isopropyl alcohol (IPA) for 60 seconds for performing development.

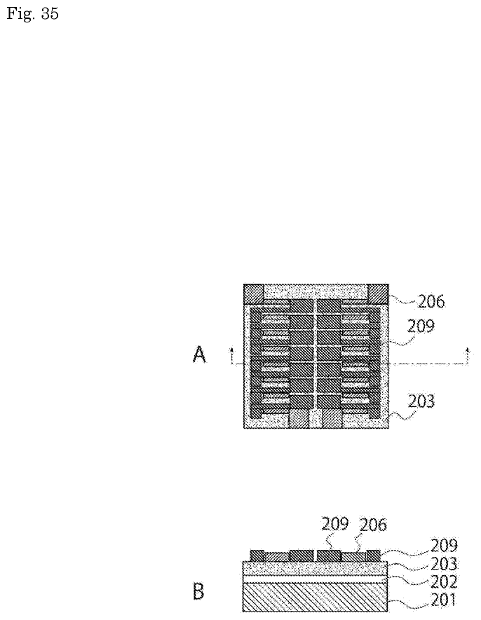

As a tenth step, as shown in FIGS. 35A and 35B, Patterning 3 of the hot point electrode is performed. Specifically, after the development, a film of a platinum metal 209 that will become the hot point electrode is formed to be 100 nm at 1 Å/sec using an electron beam heating evaporator manufactured by EIKO Co., Ltd. After the film of the platinum metal 209 is formed, the sample Si substrate 201 is taken out, immersed in an acetone solution for 600 seconds, and lifted off with an ultrasonic cleaner to complete the patterning of the hot point electrode.

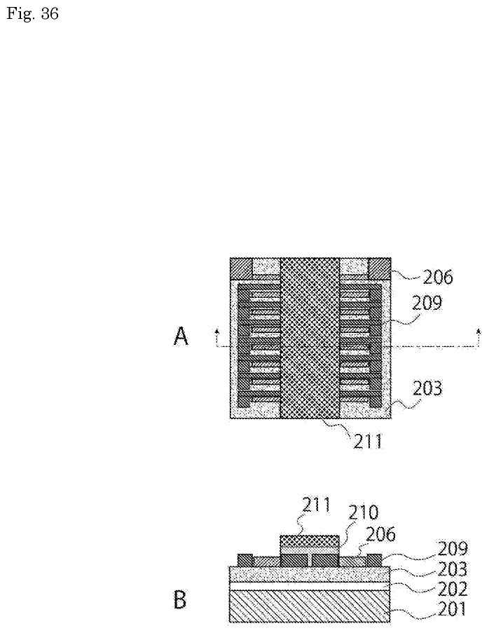

As an eleventh step, as shown in FIGS. 36A and 36B, an infrared absorption film 211 is formed. Specifically, a parylene or polyimide precursor, which is an insulating film 210, is vapor-deposited by resistance heating on the platinum metal 209 through metal mask vapor deposition. After that, the sample Si substrate 201 is set in a resistance heating type vacuum evaporator. A leak valve of the vacuum evaporator is adjusted, a degree of vacuum of the vacuum evaporator is adjusted to 100 Pa, and a film of gold set in a tungsten boat in advance is formed to be 100 nm. The obtained vapor deposition film becomes the infrared absorption film 211 called Gold Black, which has a very good absorption rate of 99.7% in the wavelength range from 400 nm in a visible region to 13 μm in a mid-infrared region.

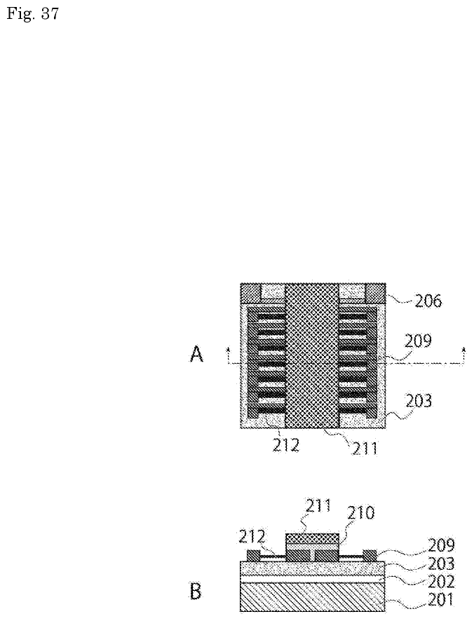

As a twelfth step, as shown in FIGS. 37A and 37B, a film of a thermal conductor (a graphene nanoribbon) 212 is formed. Specifically, the sample Si substrate 201 is set in the plasma CVD apparatus, and the pressure is reduced to 10⁻⁵ Pa. Argon as a carrier gas and methane (CH₄) as a process gas are introduced into the CVD apparatus and stand until the degree of vacuum is stabilized. When the degree of vacuum is stabilized, a plasma emitting device is set, and plasma emitting is performed for 18 seconds from the outside of the vacuum chamber. After the carrier gas and the process gas are stopped, and the pressure inside the chamber is brought to an atmospheric pressure, the sample Si substrate 201 is taken out. When observation from an oblique angle of 30 degrees is performed using a surface electron microscope (SEM), it can be confirmed that the thermal conductor 113 of a graphene nanoribbon hollow body is manufactured.

The present technology can be configured as follows:

(1)

A thermoelectric conversion element comprising:
a substrate;
a first electrode on a high temperature side which is disposed on a front surface of the substrate;
a second electrode on a low temperature side which is disposed on a front surface of the substrate;
a thermal conductor which connects the first electrode and the second electrode to each other and contains a nanostructure; and
an absorption film which is formed on a front surface of the first electrode and absorbs incident light.

(2)

The thermoelectric conversion element according to (1), wherein the absorption film is an infrared absorption film.

(3)

The thermoelectric conversion element according to (1) or (2), wherein the incident light has a wavelength in a range of 4 μm to 12 μm.

(4)

The thermoelectric conversion element according to any one of (1) to (3), wherein a material of the thermal conductor is a carbon material with which an absorption rate difference between the absorption film and the thermal conductor is 60% or more.

(5)

The thermoelectric conversion element according to any one of (1) to (4), wherein the thermal conductor has a thermal resistance of 2.5×10⁷ (K/W) or more.

(6)

The thermoelectric conversion element according to any one of (1) to (5), wherein the thermal conductor is provided at a position separated from the substrate.

(7)

The thermoelectric conversion element according to any one of (1) to (6), wherein a material of the first electrode is nickel or titanium.

(8)

The thermoelectric conversion element according to any one of (1) to (7), wherein a material of the second electrode is gold or aluminum.

(9)

The thermoelectric conversion element according to any one of (1) to (8), wherein a width of the thermal conductor increases from the first electrode toward the second electrode.

(10)

The thermoelectric conversion element according to any one of (1) to (9), wherein the absorption film is provided with a heat collection structure.

(11)

The thermoelectric conversion element according to any one of (1) to (10), wherein the first electrode and the second electrode have different thicknesses, and the thermal conductor is bent to provide curvature.

(12)

The thermoelectric conversion element according to any one of (1) to (11), wherein the substrate is formed of a thermal resonance reflection film.

(13)

A thermoelectric conversion element array comprising:
a plurality of the thermoelectric conversion elements according to any one of (1) to (12),
wherein a material of the thermal conductor is a carbon material, and the thermoelectric conversion elements are connected to each other by a metal having a polarity of thermoelectric performance different from that of the carbon material.

(14)

An infrared sensor in which a plurality of the thermoelectric conversion elements according to any one of (1) to (12) are disposed in an array.

(15)

An infrared sensor in which a plurality of the thermoelectric conversion elements according to any one of (1) to (12) are disposed in a two-dimensional array.

(16)

A method for manufacturing a thermoelectric conversion element, the method comprising:
patterning a second electrode on a low temperature side and a thermal conductor having one end connected to the second electrode on a front surface of a substrate;
patterning a first electrode on a high temperature side connected to the other end of the thermal conductor on the front surface of the substrate;
forming an absorption film that absorbs incident light on the front surface of the first electrode; and
forming the thermal conductor with a nanostructure at a position separated from the substrate.

### REFERENCE SIGNS LIST

10, 20, 30, 40, 50 Thermoelectric conversion element
11, 31, 41, 51 Substrate
12, 42, 52 Hot point electrode (first electrode)
13, 43, 53 Cold point electrode (second electrode)
14, 24, 44, 54 Thermal conductor
15, 45, 55 Absorption film
16, 17, 18 Heat collection structure
101, 201 Si film
102, 202 SiO₂ film
103, 203 SiN_{X} film
104, 107, 108, 204, 207 PMMA film
105, 109, 205, 208 PMMA film (exposed portion)
106, 206 Nickel metal
110, 209 Platinum metal
111, 210 Insulating film
112, 211 Infrared absorption film
113, 212 Graphene nanoribbon

1. A thermoelectric conversion element comprising:
a substrate;
a first electrode on a high temperature side which is disposed on a front surface of the substrate;
a second electrode on a low temperature side which is disposed on a front surface of the substrate;
a thermal conductor which connects the first electrode and the second electrode to each other and contains a nanostructure; and
an absorption film which is formed on a front surface of the first electrode and absorbs incident light.

2. The thermoelectric conversion element according to claim 1, wherein the absorption film is an infrared absorption film.

3. The thermoelectric conversion element according to claim 1, wherein the incident light has a wavelength in a range of 4 μm to 12 μm.

4. The thermoelectric conversion element according to claim 1, wherein a material of the thermal conductor is a carbon material with which an absorption rate difference between the absorption film and the thermal conductor is 60% or more.

5. The thermoelectric conversion element according to claim 1, wherein the thermal conductor has a thermal resistance of 2.5×10⁷ (K/W) or more.

6. The thermoelectric conversion element according to claim 1, wherein the thermal conductor is provided at a position separated from the substrate.

7. The thermoelectric conversion element according to claim 1, wherein a material of the first electrode is nickel or titanium.

8. The thermoelectric conversion element according to claim 1, wherein a material of the second electrode is gold or aluminum.

9. The thermoelectric conversion element according to claim 1, wherein a width of the thermal conductor increases from the first electrode toward the second electrode.

10. The thermoelectric conversion element according to claim 1, wherein the absorption film is provided with a heat collection structure.

11. The thermoelectric conversion element according to claim 1, wherein the first electrode and the second electrode have different thicknesses, and the thermal conductor is bent to provide curvature.

12. The thermoelectric conversion element according to claim 1, wherein the substrate is formed of a thermal resonance reflection film.

13. A thermoelectric conversion element array comprising:
a plurality of the thermoelectric conversion elements according to claim 1,
wherein a material of the thermal conductor is a carbon material, and the thermoelectric conversion elements are connected to each other by a metal having a polarity of thermoelectric performance different from that of the carbon material.

14. An infrared sensor in which a plurality of the thermoelectric conversion elements according to claim 1 are disposed in an array.

15. An infrared sensor in which a plurality of the thermoelectric conversion elements according to claim 1 are disposed in a two-dimensional array.

16. A method for manufacturing a thermoelectric conversion element, the method comprising:
patterning a second electrode on a low temperature side and a thermal conductor having one end connected to the second electrode on a front surface of a substrate;
patterning a first electrode on a high temperature side connected to the other end of the thermal conductor on the front surface of the substrate;
forming an absorption film that absorbs incident light on the front surface of the first electrode; and
forming the thermal conductor with a nanostructure at a position separated from the substrate.
